(19) United States
(12) Patent Application Publication
(10) Pub. No.: US 2022/0283020 A1
(43) Pub. Date: Sep. 8, 2022

(54) VIBRATION DETECTION SYSTEM

(71) Applicant: SHINKAWA LTD., Tokyo (JP)

(72) Inventors: Michael KIRKBY, Tokyo (JP); Shota NAKANO, Tokyo (JP); Hiroshi MUNAKATA, Tokyo (JP)

(73) Assignee: SHINKAWA LTD., Tokyo (JP)

(21) Appl. No.: 17/626,490

(22) PCT Filed: Sep. 3, 2020
(86) PCT No.: PCT/JP2020/033353

§ 371 Date: Jan. 11, 2022

(30) Foreign Application Priority Data
Sep. 3, 2019 (JP) 2019-160471

(51) Int. Cl. G01H 9/00

(52) U.S. Cl. CPC G01H 9/002

(57) ABSTRACT

A vibration detection system (100) detects vibration of an ultrasonic horn (12), of which the front surface is a non-specular surface, and of a capillary (13), wherein the vibration detection system (100) includes a laser light source (20) that irradiates the ultrasonic horn (12) and the capillary (13) with parallel laser light beams (21), a camera (30) having an imaging element (31) that captures an image of the ultrasonic horn (12) and the capillary (13) irradiated with the parallel laser light beams (21), and an image processing device (40) that processes the image captured by the camera (30) and displays a location where vibration occurs.

### TECHNICAL FIELD

The invention relates to a vibration detection system which detects vibration of an object under observation, and particularly relates to a vibration detection system which detects vibration of an object under observation whose front surface is non-specular.

### RELATED ART

In a wire bonding apparatus, when observing ultrasonic vibration of a tool such as a capillary, a method using a laser Doppler vibrometer is often used (see, for example, Patent Document 1).

### CITATION LIST

### Patent Literature

[Patent Literature 1] Japanese Patent Lain-Open No. 2013-125875

### SUMMARY OF INVENTION

### Technical Problem

In recent years, real-time detection of vibration on a two-dimensional surface of an object under observation is pursued. However, in the method disclosed in Patent Document 1, the vibration measurement location is limited to a dot or a line irradiated with laser light, and real-time observation of vibration on a two-dimensional surface cannot be carried out.

Therefore, an objective of the invention is to detect the vibration on a two-dimensional surface of an object under observation in a real-time manner.

### Solution to Problem

A vibration detection system according to the invention is a vibration detection system detecting vibration of an object under observation whose front surface is non-specular. The vibration detection system includes: a laser light source, irradiating the object under observation with laser light; a camera, having an imaging element imaging the object under observation irradiated with the laser light and obtaining an image; and an image processing device, processing the image imaged by the camera and displaying a vibration occurrence location.

In this way, since the vibration occurrence location is identified based on the two-dimensional image imaged by the camera, the vibration on the two-dimensional surface of the object under observation can be detected in a real-time manner.

In the vibration detection system according to the invention, it may be that an exposure time of the camera at a time of imaging is longer than a vibration cycle of the object under observation, and the camera obtains an image including an interference pattern which occurs due to interference of the laser light reflected by the front surface of the object under observation, the image processing device identifies a vibration occurrence pixel from a deviation between an image including an interference pattern at a non-vibrating time of the object under observation and an image including an interference pattern at a time of vibration obtained by the camera, and outputs an observation image including display corresponding to the vibration occurrence pixel identified in the image of the object under observation.

When the object under observation whose front surface is non-specular is irradiated with laser light, the interference pattern due to the interference of the laser light resulting from non-specular reflection appears on the front surface of the imaging element of the camera. The imaging element of the camera obtains the image of the interference pattern. Since the exposure time of the camera at the time of imaging is longer than the vibration cycle of the object under observation, when the object under observation vibrates, the camera obtains the image of a shaken interference pattern. When the image of the interference pattern is shaken, the pixel brightness intensity is changed compared with the case of non-vibrating. Therefore, a pixel whose brightness intensity at the time of vibration is changed from the brightness intensity at the non-vibrating time is identified as the vibration occurrence pixel, and, by outputting the observation image including display corresponding to the vibration occurrence pixel identified in the image of the object under observation, the vibration part of the object under observation can be visualized and displayed.

In the vibration detection system according to the invention, it may be that, in a case in which there are a predetermined number of other vibration occurrence pixels in a predetermined range around the vibration occurrence pixel that is identified, the image processing device maintains identification of such pixel as the vibration occurrence pixel, and in a case in which the predetermined number of other vibration occurrence pixels are not present in the predetermined range, the image processing device cancels the identification of such pixel as the vibration occurrence pixel.

Accordingly, the identification of a pixel which actually does not vibrate as the vibration occurrence pixel due to noise can be suppressed, and vibration detection can be performed more accurately.

In the vibration detection system according to the invention, it may be that the laser light source irradiates the object under observation with parallel laser light with a single wavelength.

Through the irradiation of the parallel light with a single wavelength, the interference pattern of the laser light reflected by the non-specular surface appears more clearly, and the speckle pattern imaged by the camera is clearer. Accordingly, the vibration detection can be performed more accurately.

### Effects of Invention

The invention is capable of detecting the vibration on a two-dimensional surface of an object under observation in a real-time manner.

### BRIEF DESCRIPTION OF DRAWINGS

FIG. 1 is a system diagram illustrating a configuration of a vibration detection system according to an embodiment.

FIG. 2 is a schematic diagram illustrating a state in which parallel laser light reflected by a surface of a capillary is incident to an imaging element of a camera.

FIG. 3 is a schematic diagram illustrating an image captured by the camera.

FIG. 4 is a schematic diagram illustrating pixels of the imaging element of the camera.

FIG. 5 is a flowchart illustrating an image process by using an image processing device.

FIG. 6 is a schematic diagram illustrating an observation image output to a monitor.

### DESCRIPTION OF EMBODIMENTS

In the following, a vibration detection system 100 of an embodiment is described with reference to the drawings. In the following description, the vibration detection system 100 observes an ultrasonic horn 12 or a capillary 13 of a wire bonding apparatus 10 as the object under observation to detect the vibration thereof.

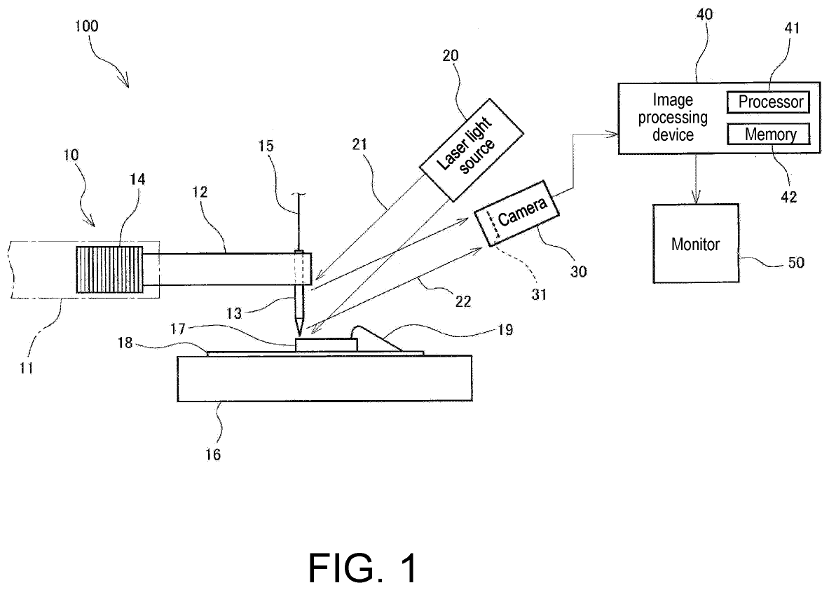

Firstly, the wire bonding apparatus 10 including the ultrasonic horn 12 and the capillary 13, as the objects under observation, is briefly described with reference to FIG. 1. The wire bonding apparatus 10 includes a bonding arm 11, the ultrasonic horn 12, the capillary 13, an ultrasonic vibrator 14, and a bonding stage 16.

The capillary 13 is attached to the front end of the ultrasonic horn 12, and the ultrasonic vibrator 14 is attached to the rear end of the ultrasonic horn 12. The ultrasonic horn 12 vibrates ultrasonically through the ultrasonic vibration generated by the ultrasonic vibrator 14, and ultrasonically vibrates the capillary 13. The ultrasonic horn 12 is connected to the bonding arm 11, and is driven in a direction in which the capillary 13 approaches and leaves the bonding stage 16 by a driving mechanism not shown herein. The bonding stage 16 suctions and fixes a substrate 18 in which a semiconductor element 17 is attached to a surface. The wire bonding apparatus 10 presses, by using the driving mechanism not shown herein, the front end of the capillary 13 onto an electrode of the semiconductor element 17 to bond a wire 15 to the electrode of the semiconductor element 17. Then, the capillary 13 is moved onto an electrode of the substrate 18, and the front end of the capillary 13 is pressed onto the electrode of the substrate 18 to bond the wire 15 to the electrode of the substrate 18. Accordingly, the wire bonding apparatus 10 connects the electrode of the semiconductor element 17 and the electrode of the substrate 18 by a loop wire 19. Accordingly, in the bonding operation, the ultrasonic horn 12 and the capillary 13 vibrate ultrasonically. The vibration detection system 100 of the embodiment performs detection and display of the vibration on a two-dimensional surface of the ultrasonic horn 12 or the capillary 13. The surface of the ultrasonic horn 12 or the capillary 13 is non-specular and has fine unevenness.

As shown in FIG. 1, the vibration detection system 100 is configured by a laser light source 20, a camera 30, and an image processing device 40.

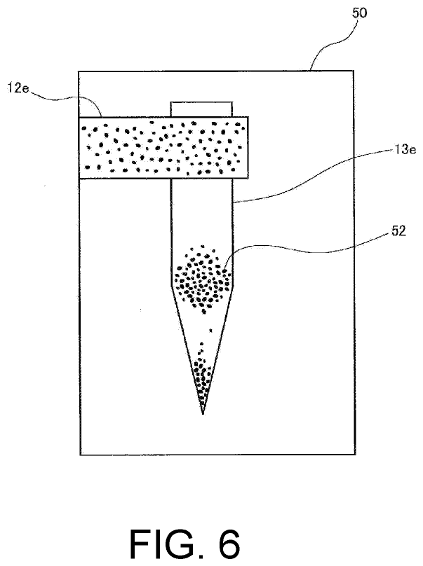

The laser light source 20 converts laser light of a single wavelength output from a laser oscillator by using a beam expander into parallel laser light 21, and irradiates the ultrasonic horn 12 or the capillary 13 with the parallel laser light 21. The camera 30 includes an imaging element 31, and captures a two-dimensional image of the ultrasonic horn 12 or the capillary 13 irradiated with the parallel laser light 21. The image processing device 40 processes the two-dimensional image captured by the camera 30 and identifies a vibration occurrence location, and outputs and displays two-dimensional observation images 12e and 13e (see FIG. 6) making the display of a vibration part different from other parts to a monitor 50. The image processing device 40 is a computer including a processor 41 performing an information process and a memory 42 inside.

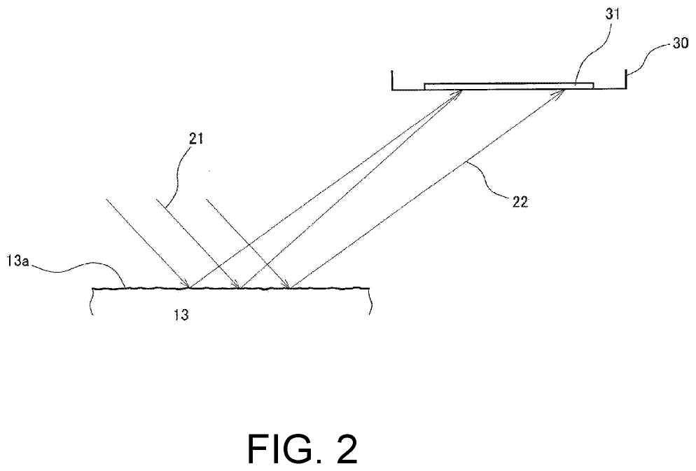

In the following, the operation of the vibration detection system 100 according to the embodiment is described with reference to FIGS. 2 to 6.

As shown in FIG. 2, a surface 13a of the capillary 13 is non-specular and has fine unevenness. When the surface 13a of the capillary 13 is irradiated with the parallel laser light 21, the parallel laser light 21 is reflected by the surface 13a of the capillary 13 to a random direction. Reflected laser light 22 reflected through the non-specular reflection interferes with each other, and an interference pattern of the reflected laser light 22 appears on the surface of the imaging element 31 of the camera 30.

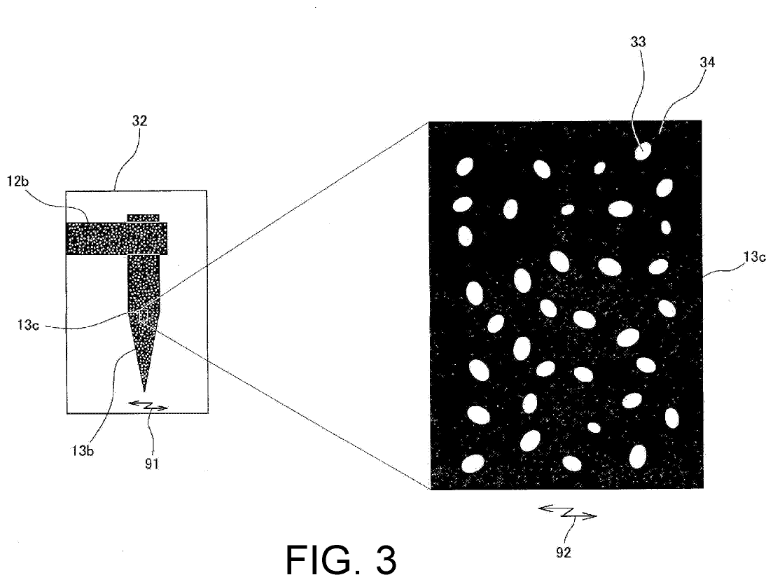

Since the interference pattern has a bright portion in which the light intensity is high and a dark portion in which the light intensity is low, the imaging element 31 of the camera 30, as shown in FIG. 3, obtains an image 13c with a speckled pattern configured by a plurality of bright portions 33 and dark portions 34 as an interference pattern.

Accordingly, when the ultrasonic horn 12 and the capillary 13 are imaged by the camera 30, the camera 30 obtains an image 12b of the ultrasonic horn 12 with a speckled pattern and an image 13b of the capillary 13 with a speckled pattern, as shown in a visual field 32 of FIG. 13. The images 12b and 13b are images including interference patterns.

The light exposure time of the camera 30 at the time of imaging is longer than a vibration cycle of the ultrasonic vibration of the ultrasonic horn 12 and the capillary 13. Therefore, in a region forming a peak of the vibration, when the ultrasonic horn 12 and the capillary 13 vibrate ultrasonically, the image 12b of the ultrasonic horn 12 with the speckled pattern and the image 13b of the capillary 13 with the speckled pattern on the imaging element 31 during exposure shake as indicated by arrows 91 and 92. Meanwhile, in a region of a node of the vibration, even if the ultrasonic horn 12 and the capillary 13 vibrate ultrasonically, the image 12b and the image 13b on the imaging element 31 during exposure do not shake.

In the regions in which the images 12b and 13b shake during exposure, the brightness intensity of pixels 36 of the imaging element 31 changes with respect to the brightness intensity of a static state in which the ultrasonic horn 12 and the capillary 13 do not vibrate ultrasonically or the brightness intensity of a non-vibrating state. As an example, in a region of the peak of vibration, the brightness intensity of the pixel 36 is greater than the brightness intensity at the non-vibrating time.

Meanwhile, in the case in which the images 12b and 13b do not shake during exposure due as the node of vibration, the images 12b and 13b are substantially the same as the case of images 12a and 13b where the ultrasonic horn 12 and the capillary 13 are in a static state or in a non-vibrating state. Therefore, in the region of the node of vibration in which the images 12b and 13b do not shake during exposure, the brightness intensity of the pixel 36 of the imaging element 31 is substantially the same with respect to the brightness intensity of the static state in which the ultrasonic horn 12 and the capillary 13 do not vibrate ultrasonically or the brightness intensity of the non-vibrating state.

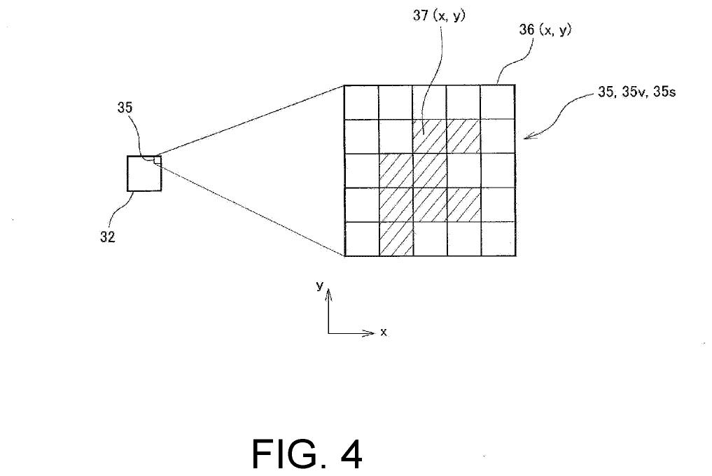

Therefore, as shown in FIG. 4, the processor 41 of the image processing device 40 identifies, as a vibration occurrence pixel 37, a pixel 36 whose brightness intensity changes from the brightness intensity at the time of being static without ultrasonic vibration or the brightness intensity at the non-vibrating time. Here, the brightness intensity is a detected degree of brightness of the pixel 36, and may be represented in 256 gradations from 0 to 255.

The image processing device 40 performs a below-described process on the respective pixels 36 of an image frame 35, which is a region of the two-dimensional image of the visual field 32 on which one image process is performed, and identifies the vibration occurrence pixel 37. In the following description, the coordinates (x, y) described after a symbol represents the coordinates (x, y) of the two-dimensional image frame 35. For example, the pixel 36 (x, y) represents the pixel 36 at the coordinates (x, y).

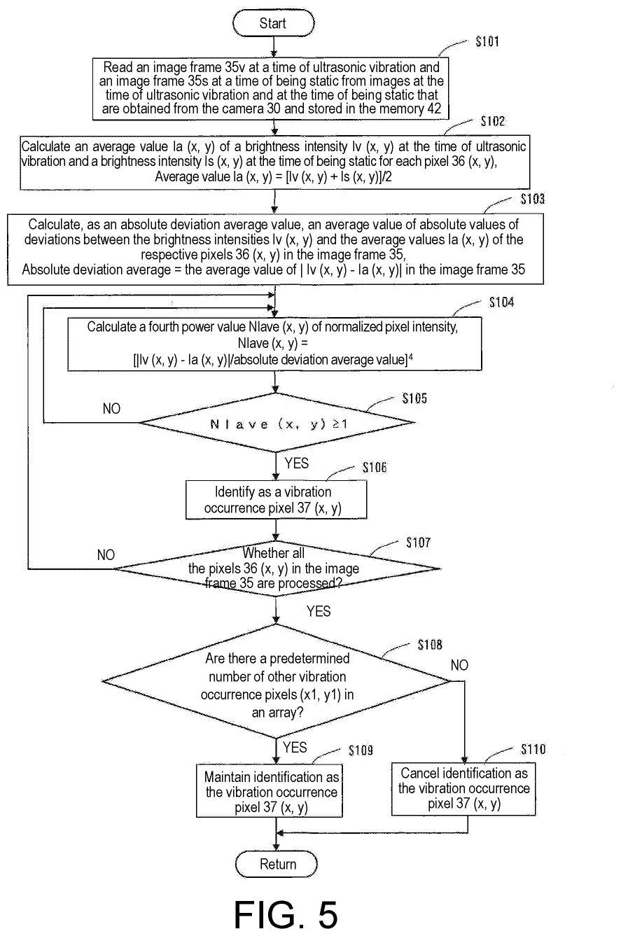

As shown in Step S101 of FIG. 5, the processor 41 of the image processing device 40 reads an image frame 35v at the time of ultrasonic vibration and an image frame 35s at the time of being static from the two-dimensional image at the time of ultrasonic vibration and the two-dimensional image at the time of being static or non-vibrating that are obtained from the camera 30 and stored in the memory 42.

As shown in Step S102 of FIG. 5, the processor 41 calculates an average value Ia (x, y) of a brightness intensity Iv (x, y) at the time of ultrasonic vibration and a brightness intensity Is (x, y) at the time of being static for each pixel 36 (x, y).

Average value Ia(x,y)=[Iv(x,y)+Is(x,y)]/2

As shown in Step S103 in FIG. 5, the processor 41 calculates, as an absolute deviation average value, an average value of the absolute values of the deviations between the brightness intensities Iv (x, y) at the time of ultrasonic vibration and the average values Ia (x, y) of the respective pixels 36 (x, y) in the image frame 35.

Absolute deviation average=the average value of |Iv(x,y)−Ia(x,y)| in the image frame 35

As shown in Step S104 of FIG. 5, the processor 41 calculates a fourth power value NIave (x, y) of normalized pixel intensity according to (Formula 1) in the following.

NIave(x,y)=[|Iv(x,y)−Ia(x,y)|/absolute deviation average value]⁴ (Formula 1)

As shown in Step S105 of FIG. 5, in the case where NIave (x, y) is equal to or greater than 1, the processor 41 determines that the change of the brightness intensity of this pixel 36 (x, y) is significant, proceeds to Step S106 of FIG. 5 to identify the pixel 36 (x, y) as the vibration occurrence pixel 37 (x, y), and proceeds to Step S107. In Step S107, in the case of determining that not all of the pixels 36 (x, y) of the image frame 35 are processed, the processor 41 returns to Step S104 to process the next pixel 36 (x, y). Meanwhile, in the case of determining as “NO” in Step S105 of FIG. 5, the processor 41 returns to Step S104 to process the next pixel 36 (x, y). If the processor 41 has calculated NIave (x, y) of all of the pixels 36 (x, y) in the image frame 35 and identified the vibration occurrence pixel 37 (x, y) in the image frame 35, the processor 41 determines “YES” in Step S107 of FIG. 5 to proceed to Step S108 of FIG. 5.

In Step S108 of FIG. 5, the processor 41 determines whether there are only a predetermined number of other vibration occurrence pixels 37 (x1, y1) within a predetermined range around one vibration occurrence pixel 37 (x, y). For example, the processor 41 may set a square array of 5×5 pixels 36 with the vibration occurrence pixel 37 (x, y) as the center as the predetermined range, and determine whether there are 7 to 8 other vibration occurrence pixels 37 (x1, y1) therein. Then, in the case of determining as “YES” in Step S108 of FIG. 5, the change of the brightness intensity of the pixel 36 (x, y) is determined as resulting from ultrasonic vibration, and the flow proceed to Step S109 of FIG. 5 to maintain the identification of the pixel 36 (x, y) as the vibration occurrence pixel 37 (x, y).

Meanwhile, in the case where there are no 7 to 8 other vibration occurrence pixels 37 (x1, y1) in the array, the change of the brightness intensity of the pixel 36 (x, y) is determined as not resulting from ultrasonic vibration, and the flow proceed to Step S110 to cancel the identification of the pixel 36 (x, y) as the vibration occurrence pixel 37 (x, y).

Then, the processor 41 confirms the identification of the vibration occurrence pixel 37 (x, y). The processor 41 performs the above process in each image frame 35 and confirms the vibration occurrence pixels 37 (x, y) regarding all of the pixels 36 (x, y) of the imaging element 31.

As shown in FIG. 6, the processor 41 visualizes and displays the vibration on the two-dimensional surfaces of the ultrasonic horn 12 and the capillary 13 by outputting the observation images 12e and 13e with display corresponding to the identified vibration occurrence pixels 37 (x, y) with respect to the images of the ultrasonic horn 12 and the capillary 13.

The observation images 12e and 13e can be presented in various forms. In FIG. 5, as an example, red dots 52 are superimposed and displayed on portions corresponding to the vibration generating pixels 37 of a general image obtained by irradiating the ultrasonic horn 12 and the capillary 13 with a non-interfering light beam such as an electric lamp. By displaying in such manner, a large number of the red dots 52 are shown in the region as the peak of the vibration, and substantially no red dots are shown in a portion as the node of the vibration. In the example shown in FIG. 5, the ultrasonic horn 12, the middle portion of the capillary 13 in which the diameter changes, and the front end portion of the capillary 13, which show a large number of the red dots 52, are peaks of the vibration, and the remaining portions are nodes of the vibration.

As described above, since the vibration detection system 100 of the embodiment processes the two-dimensional images of the ultrasonic horn 12 and the capillary 13 and displays the images as the two-dimensional observation images 12e and 13e, the vibration on the two-dimensional surfaces of the ultrasonic horn 12 and the capillary 13 can be detected in a real-time manner.

In the above description, the vibration detection system 100 is described as detecting the vibration of the ultrasonic horn 12 and the capillary 13 of the wire bonding apparatus 10. However, the vibration detection system 100 may also be applied to detect the vibration of other parts of the wire bonding apparatus 10.

For example, at the time of bonding of the wire bonding apparatus 10 shown in FIG. 1, the semiconductor element 17 is irradiated with the parallel laser light 21, and the vibration of the semiconductor element 17 can be detected. Then, in the case where the semiconductor element 17 vibrates greatly, the vibration energy from the capillary 13 is consumed for vibration other than bonding, and it can be determined that the bonding is not properly performed. Similarly, in the case where whether the substrate 18 vibrates greatly is detected, and the substrate 18 vibrates greatly, the vibration energy from the capillary 13 is consumed for vibration other than bonding, and it can be determined that the bonding is not properly performed.

Moreover, the vibration detection system 100 can also be applied to an apparatus other than the wire bonding apparatus 10, such as being applied to detecting the vibration of each part of other semiconductor manufacturing apparatuses, such as a die bonding apparatus.

In the above description, the laser light source 20 is described as irradiating the object under observation with the parallel laser light 21 with a single wavelength. However, the invention is not limited thereto. That is, the wavelength may exhibit a slight width, and the laser light source 20 may irradiate laser light which is not parallel light. Moreover, the intensity of the laser light may vary to a certain extent. Also, in the above description, the image of the interference pattern is described as a speckled pattern including multiple bright portions 33 and dark portions 34. However, the invention is not limited thereto. The pattern may also be other patterns such as a striped pattern.

Furthermore, in the case where the vibration of the object under observation is not uni-directional, multiple laser light sources 20 and cameras 30 may be prepared, and, by irradiating the object under observation with laser light from multiple directions and imaging the object under observation from multiple directions by using multiple cameras 30, the vibration in multiple directions can be detected.

### REFERENCE SIGNS LIST

10: Wire bonding apparatus; 11: Bonding arm; 12: Ultrasonic horn; 12a, 13b, 13c: Image; 12e, 13e: Observation image; 13: Capillary; 13a: Surface; 14: Ultrasonic vibrator; 15: Wire; 16: Bonding stage; 17: Semiconductor element; 18: Substrate; 19: Loop wire; 20: Laser light source; 21: Parallel laser light; 22: Reflected laser light; 30: Camera; 31: Imaging element; 32: Visual field; 33: Bright portion; 34: Dark portion; 35, 35v, 35s: Image frame; 36: Pixel; 37: Vibration occurrence pixel; 40: Image processing device; 41: Processor; 42: Memory; 50: Monitor; 52: Red dot; 100: Vibration detection system.

1. A vibration detection system, detecting vibration of an object under observation whose front surface is non-specular, the vibration detection system comprising:
a laser light source, irradiating the object under observation with laser light;
a camera, having an imaging element imaging the object under observation irradiated with the laser light and obtaining an image; and
an image processing device, processing the image imaged by the camera and displaying a vibration occurrence location,
wherein an exposure time of the camera at a time of imaging is longer than a vibration cycle of the object under observation, and the camera obtains an image comprising an interference pattern which occurs due to interference of the laser light reflected by the front surface of the object under observation, and
the image processing device identifies a vibration occurrence pixel from a deviation between an image comprising an interference pattern at a non-vibrating time of the object under observation and an image comprising an interference pattern at a time of vibration obtained by the camera, and outputs an observation image including display corresponding to the vibration occurrence pixel identified in the image of the object under observation.

2. (canceled)

3. The vibration detection system as claimed in claim 1, wherein in a case in which there are a predetermined number of other vibration occurrence pixels in a predetermined range around the vibration occurrence pixel that is identified, the image processing device maintains identification of such pixel as the vibration occurrence pixel, and in a case in which there are no predetermined number of other vibration occurrence pixels in the predetermined range, the image processing device cancels the identification of such pixel as the vibration occurrence pixel.

4. The vibration detection system as claimed in claim 1, wherein the laser light source irradiates the object under observation with parallel laser light with a single wavelength.

5. The vibration detection system as claimed in claim 3, wherein the laser light source irradiates the object under observation with parallel laser light with a single wavelength.
